(19) United States
(12) Patent Application Publication
(10) Pub. No.: US 2025/0336897 A1
(43) Pub. Date: Oct. 30, 2025

(54) SEMICONDUCTOR PACKAGE

(71) Applicant: Samsung Electronics Co., Ltd., Suwon-si (KR)

(72) Inventor: Jung Hoon KANG, Suwon-si (KR)

(21) Appl. No.: 19/006,666

(22) Filed: Dec. 31, 2024

(30) Foreign Application Priority Data
Apr. 26, 2024 (KR) 10-2024-0056047

(51) Int. Cl. H01L 25/07; H01L 23/00; H01L 23/538; H01L 25/00

(52) U.S. Cl. CPC H01L 25/074; H01L 23/5385; H01L 24/08; H01L 25/50; H01L 2224/08146; H01L 2224/08225; H01L 2225/06541; H01L 2225/06589

(57) ABSTRACT

A semiconductor package includes a first semiconductor chip; an insulating layer on a side face of the first semiconductor chip; a through via which extends through the insulating layer; a wiring structure which is electrically connected to the first semiconductor chip and the through via, on the first semiconductor chip and the insulating layer; a chip stack on the wiring structure; a molding layer on at least a part of the chip stack and on the wiring structure; and a conductive post which extends through the molding layer and is electrically connected to the wiring structure.

### CROSS-REFERENCE TO RELATED APPLICATION

This application claims priority from Korean Patent Application No. 10-2024-0056047, filed Apr. 26, 2024, in the Korean Intellectual Property Office, and all the benefits accruing therefrom, the contents of which in its entirety are herein incorporated by reference.

### BACKGROUND

### 1. Field

The present disclosure relates to a semiconductor package.

### 2. Description of the Related Art

In accordance with the development of the electronics industry and demands of users, there are demands for miniaturization and lighter weight of electronic components mounted on electronic products. To satisfy such demands, semiconductor packages mounted on electronic components may be required to process a high capacity of data while being small in volume. Therefore, a semiconductor package including a plurality of chips that perform various functions has been proposed.

To address the problem of heat generated by the operation of the plurality of chips, research for improving the heat dissipation performance of semiconductor packages is being conducted.

### SUMMARY

Aspects of the present disclosure provide a semiconductor package having improved product reliability by dispersing heat generated by a semiconductor chip.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to some example embodiments of the present inventive concepts, a semiconductor package includes a first semiconductor chip; an insulating layer on a side face of the first semiconductor chip; a through via which extends through the insulating layer; a wiring structure which is electrically connected to the first semiconductor chip and the through via, on the first semiconductor chip and the insulating layer; a chip stack on the wiring structure; a molding layer on at least a part of the chip stack and on the wiring structure; and a conductive post which extends through the molding layer and is electrically connected to the wiring structure.

According to some example embodiments of the present inventive concepts, a semiconductor package includes an insulating layer; a first logic semiconductor chip in the insulating layer; a through via inside the insulating layer, spaced apart from the first logic semiconductor chip; a wiring structure on the insulating layer, electrically connected to the first logic semiconductor chip and the through via; and a first chip stack, which includes stacked first memory semiconductor chips that are configured without a buffer chip, on the wiring structure.

According to some example embodiments of the present inventive concepts, a semiconductor package includes a package substrate; a first semiconductor chip on the package substrate; an insulating layer on a side face of the first semiconductor chip; a through via which extends through the insulating layer; a wiring structure which is electrically connected to the first semiconductor chip and the through via, on the first semiconductor chip and the insulating layer; a chip stack on the wiring structure and electrically connected thereto; a molding layer on at least a part of the chip stack and on the wiring structure; a conductive post which extends through the molding layer and is electrically connected to the wiring structure; a heat transfer material layer on the molding layer; and a heat dissipation member on the heat transfer material layer.

### BRIEF DESCRIPTION OF THE DRAWINGS

The above and other aspects and features of the present disclosure will become more apparent by describing in detail example embodiments thereof with reference to the attached drawings, in which:

FIG. 1 is a diagram that illustrates a semiconductor package according to some embodiments;

FIGS. 2 to 10 are diagrams that further illustrate the semiconductor package according to some embodiments; and

FIGS. 11 to 16 are intermediate stage diagrams that illustrate a method for fabricating a semiconductor package according to some embodiments.

### DETAILED DESCRIPTION OF THE EMBODIMENTS

Hereinafter, embodiments of the present disclosure will be described as follows with reference to the accompanying drawings in which example embodiments of the inventive concept are shown. The same reference numerals are used for the same elements in the drawings, and redundant descriptions thereof will be omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It is noted that aspects described with respect to one embodiment may be incorporated in different embodiments although not specifically described relative thereto. That is, all embodiments and/or features of any embodiments can be combined in any way and/or combination.

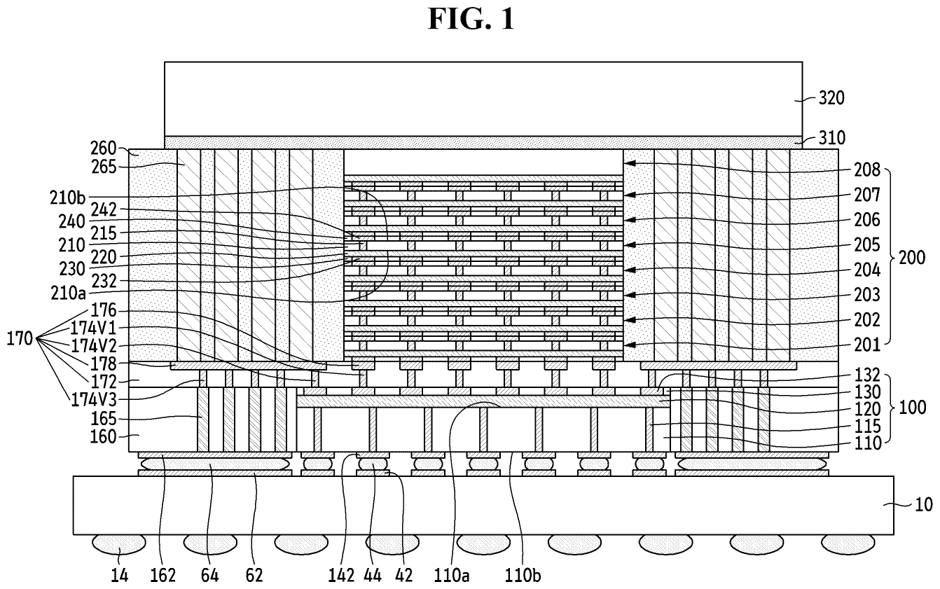

FIG. 1 is diagram that illustrates a semiconductor package according to some embodiments.

Referring to FIG. 1, the semiconductor package may include a package substrate 10, an external terminal 14, a first connection terminal 44, a second connection terminal 64, a first semiconductor chip 100, an insulating layer 160, a through via 165, a wiring structure 170, a chip stack 200, a molding layer 260, a conductive post 265, a heat transfer material layer 310, and a heat dissipation member 320.

The package substrate 10 may be a substrate for a semiconductor package. For example, the package substrate 10 may be a printed circuit board (PCB). An external terminal 14 may be disposed on a lower side of the package substrate 10. The package substrate 10 may be mounted on a main board or the like of an electronic device through the external terminal 14.

The external terminal 14 may include a conductive material, for example, at least one of solder, tin (Sn), silver (Ag), copper (Cu), and aluminum (Al). The external terminal 14 may have various shapes, such as a land, a ball, a pin, and a pillar. The number, intervals, placement and the like of the external terminals 14 are not limited to those shown in the drawings, and may vary depending on the design.

The first semiconductor chip 100 may be disposed on an upper side of the package substrate 10. The first semiconductor chip 100 may include a first semiconductor substrate 110, a first through electrode 115, a first semiconductor element layer 120, a chip insulating layer 130, and a chip pad 132.

Hereinafter, the upper side, the lower side, an upper part, and a lower part are defined on the basis of a direction toward the first semiconductor chip 100 in the package substrate 10. That is, an upper surface of the package substrate 10 opposite the lower surface of the package substrate 10 on which the external terminal 14 is placed may serve as a base reference plane. A vertical direction may, therefore, be a direction perpendicular to the upper surface of the package substrate 10 and a horizontal direction may be a direction parallel to the upper surface of the package substrate 10.

The first semiconductor substrate 110 may include a first front side 110a and a first rear side 110b that are opposite to each other. The first front side 110a may be an active side on which a semiconductor element is formed. For example, the first front side 110a may include a conductive region, for example, a well doped with impurities. The first front side 110a may also have various element isolation structures, such as an insulating region, for example, a shallow trench isolation (STI).

The first semiconductor element layer 120 may be disposed on the first front side 110a of the first semiconductor substrate 110. The chip insulating layer 130 may be disposed on the first semiconductor element layer 120. The first semiconductor element layer 120 may be disposed between the chip insulating layer 130 and the first semiconductor substrate 110. The chip pad 132 may be disposed in the chip insulating layer 130. The chip pad 132 may be electrically connected to the first semiconductor element layer 120. The first through electrode 115 may penetrate or extend through the first semiconductor substrate 110. The first through electrode 115 may be electrically connected to the first semiconductor element layer 120.

The insulating layer 160 may wrap or be on at least a part of the first semiconductor chip 100. The insulating layer 160 may wrap or be on a side face of the first semiconductor chip 100. The first semiconductor chip 100 may be disposed in the insulating layer 160. For example, the upper face of the insulating layer 160 may be coplanar with the upper face of the first semiconductor chip 100, and the lower face of the insulating layer 160 may be coplanar with the lower face of the first semiconductor chip 100. The insulating layer 160 may include, for example, an oxide.

The through via 165 may penetrate or extend through the insulating layer 160. The through via 165 may be disposed inside the insulating layer 160. The through via 165 may be spaced apart from the first semiconductor chip 100. For example, the through via 165 may be arranged to surround at least a part of the first semiconductor chip 100 from a planar viewpoint parallel to the upper side of the package substrate 10. The through via 165 may include a metal.

The first semiconductor chip 100 and the through via 165 may be mounted on the package substrate 10. The first semiconductor chip 100 and the through via 165 may be electrically connected to the package substrate 10.

For example, the first pad 142 and the second pad 162 may be disposed on the lower face of the insulating layer 160. The first pad 142 may be disposed on the lower face of the first semiconductor chip 100, and may be electrically connected to the first semiconductor chip 100. The second pad 162 may be disposed on the lower face of the through via 165, and may be electrically connected to the through via 165. First and second substrate pads 42 and 62 may be disposed on the upper side of the package substrate 10. The first and second substrate pads 42 and 62 may be electrically connected to the package substrate 10. A first connection terminal 44 may be disposed between the first pad 142 and the first substrate pad 42. A second connection terminal 64 may be disposed between the second pad 162 and the second substrate pad 62.

The sizes, placement forms, and the like of each of the first pad 142 and the second pad 162, the first connection terminal 44 and the second connection terminal 64, and the first substrate pad 42 and the second substrate pad 62 are not limited to those shown in the drawings, and may vary depending on the design.

Each of the first connection terminal 44 and the second connection terminal 64 may include a conductive material, for example, solder, tin (Sn), silver (Ag), copper (Cu), and/or aluminum (Al). Each of the first connection terminals 44 and the second connection terminals 64 may have various shapes, such as a land, a ball, a pin, and a pillar.

The wiring structure 170 is disposed on the insulating layer 160 and the first semiconductor chip 100. The wiring structure 170 is electrically connected to the first semiconductor chip 100 and the through via 165. The wiring structure 170 may include a wiring insulating layer 172, wiring vias 174V1, 174V2 and 174V3, a wiring pad 176, and a thermal pad 178. The wiring vias 174V1, 174V2 and 174V3, the wiring pad 176, and the thermal pad 178 may be disposed in the wiring insulating layer 172.

The first and second wiring vias 174V1 and 174V2 may be disposed on the first semiconductor chip 100. The first and second wiring vias 174V1 and 174V2 may be electrically connected to the first semiconductor chip 100. For example, the first and second wiring vias 174V1 and 174V2 may be electrically connected to the chip pad 132 of the first semiconductor chip 100. The third wiring via 174V3 may be disposed on the through via 165. The third wiring via 174V3 may be electrically connected to the through via 165. For example, the third wiring via 174V3 may be electrically connected to the through via 165.

The wiring pad 176 may be electrically connected to the first wiring via 174V1. The wiring pad 176 may be electrically connected to the first semiconductor chip 100. For example, the wiring pad 176 may be connected to the first wiring via 174V1.

The thermal pad 178 may be electrically connected to the second and third wiring vias 174V2 and 174V3. For example, the thermal pad 178 may be connected to the second and third wiring vias 174V2 and 174V3. The thermal pad 178 may be electrically connected to the first semiconductor chip 100 and the through via 165.

For example, the wiring structure 170 may include multilayered wiring patterns, and via patterns that electrically connect the wiring patterns. The wiring pad 176 may be a wiring pattern that is disposed at the top of the wiring pattern and electrically connected to the chip stack 200, and the thermal pad 178 may be a wiring pattern that is disposed at the top of the wiring pattern and electrically connected to the conductive post 265. The first and second wiring vias 174V1 and 174V2 may be via patterns that are disposed at the bottom of the via patterns and electrically connected to the first semiconductor chip 100, and the third wiring via 174V3 may be a via pattern that is disposed at the bottom of the via patterns and electrically connected to the through via 165.

The wiring insulating layer 172 may include an oxide (e.g., silicon oxide). The wiring vias 174V1, 174V2 and 174V3, the wiring pad 176, and the thermal pad 178 may each include a metal.

The chip stack 200 is disposed on the first semiconductor chip 100. The chip stack 200 may be electrically connected to the first semiconductor chip 100. The chip stack 200 may include stacked second semiconductor chips 201 to 208. The number of second semiconductor chips 201 to 208 included in the chip stack 200 may vary.

Each of the second semiconductor chips 201 to 207 may include a second semiconductor substrate 210, a second through electrode 215, a second semiconductor element layer 220, a first bonding insulating layer 230, a first bonding pad 232, a second bonding insulating layer 240, and a second bonding pad 242. The second semiconductor chip 208 may include a second semiconductor substrate 210, a second semiconductor element layer 220, a first bonding insulating layer 230, and a first bonding pad 232.

The second semiconductor substrate 210 may include a second front side 210a and a second back side 210b that are opposite each other. The second front side 210a may be an active side on which a semiconductor device is formed. For example, the second front side 210a may include a conductive region, for example, a well doped with impurities. The second front side 210a may also have various element isolation structures, such as an insulating region, for example, a shallow trench isolation (STI).

Each of the first semiconductor substrate 110 and the second semiconductor substrate 210 may be, for example, bulk silicon or silicon on insulator (SOI). Each of the first semiconductor substrate 110 and the second semiconductor substrate 210 may be a silicon substrate or may include other materials, for example, silicon germanium, indium antimonide, lead telluride, indium arsenide, indium phosphide, gallium arsenide or gallium antimonide. In other embodiments, each of the first semiconductor substrate 110 and the second semiconductor substrate 210 may be an epitaxial layer formed on a base substrate.

The second semiconductor element layer 220 may be formed on the second front side 210a of the second semiconductor substrate 210. The first semiconductor element layer 120 and the second semiconductor element layer 220 may each include various types of individual devices and/or interlayer insulating films.

The individual devices may include various microelectronic devices, for example, a metal-oxide-semiconductor field effect transistor (MOSFET), such as a complementary metal-insulator-semiconductor transistor (CMOS transistor), a system LSI (large scale integration), a flash memory, a DRAM, a SRAM, an EEPROM, a PRAM, a MRAM, a RRAM, an image sensor such as a CIS (CMOS imaging sensor), an micro-electro-mechanical system (MEMS), an active element, a passive element, and the like. The first semiconductor element layer 120 and the second semiconductor element layer 220 may each include wiring connected to the individual devices.

The first bonding insulating layer 230 may be disposed on the second semiconductor element layer 220. The second semiconductor element layer 220 may be disposed between the second semiconductor substrate 210 and the first bonding insulating layer 230. The first bonding pads 232 may be disposed in the first bonding insulating layer 230. The first bonding pads 232 may be electrically connected to the second semiconductor element layer 220.

The second bonding insulating layer 240 may be disposed on the second side 210b of the second semiconductor substrate 210. The second bonding pad 242 may be disposed in the second bonding insulating layer 240.

The second through electrode 215 may penetrate or extend through the second semiconductor substrate 210. The second through electrode 215 may be electrically connected to the second bonding pad 242. The second through electrode 215 may be electrically connected to the second semiconductor element layer 220. The second through electrode 215 may be electrically connected to the first bonding pad 232 through the second semiconductor element layer 220.

The second semiconductor chips 201 to 208 adjacent to each other may be bonded. In some embodiments, the second semiconductor chips 201 to 208 may be bonded to each other by a hybrid bonding technique. The first bonding insulating layer 230 and the second bonding insulating layer 240 adjacent to each other, and the first bonding pad 232 and the second bonding pad 242 adjacent to each other may be bonded by coming into contact with each other.

For example, each of the second bonding insulating layer 240 and the second bonding pad 242 of the second semiconductor chip 201 may come into contact with and be bonded to each of the first bonding insulating layer 230 and the first bonding pad 232 of the second semiconductor chip 202. The second semiconductor chips 201 to 208 may be electrically connected by the first bonding pad 232 and the second bonding pad 242. An interface between the first bonding insulating layer 230 and the second bonding insulating layer 240 that come into contact with each other may not be distinguished.

Each of the first bonding insulating layer 230 and the second bonding insulating layer 240 may include an insulating material, for example, SiO, SiN, SiCN, SiOC, SiON, and/or SiOCN. Each of the first bonding pad 232 and the second bonding pad 242 may include metals, for example, copper (Cu), tungsten (W), aluminum (Al), tungsten nitride (WN), tantalum nitride (TaN), and/or titanium nitride (TiN). When each of the first bonding insulation layer 230 and the second bonding insulation layer 240 is formed of an oxide (e.g., silicon oxide), and each of the first bonding pad 232 and the second bonding pad 242 is formed of copper (Cu), the hybrid bonding technique may be a copper-oxide hybrid bonding technique.

The chip stack 200 may be mounted on the wiring structure 170. The chip stack 200 is electrically connected to the wiring structure 170. In some embodiments, the chip stack 200 may be bonded to the wiring insulation layer 172 and the wiring pad 176. The chip stack 200 may be bonded to the wiring insulation layer 172 and the wiring pad 176 by a hybrid bonding technique. The wiring insulation layer 172 and the first bonding insulation layer 230 of the second semiconductor chip 201 adjacent to each other, and the wiring pad 176 and the first bonding pad 232 adjacent to each other may come into contact with and be bonded to each other.

The chip stack 200 may be a high bandwidth memory (HBM) that does not include a buffer chip, and each of the second semiconductor chips 201 to 208 may be a memory semiconductor chip. The first semiconductor chip 100 is a logic semiconductor chip, and may also serve as a buffer chip of the chip stack 200. The first semiconductor chip 100 may transfer signals and/or power from the outside or from an external source to the chip stack 200, or may transfer signals from the chip stack 200 to the outside or to an external source.

The logic semiconductor chip may be, for example, an application processor (AP), such as a central processing unit (CPU), a graphic processing unit (GPU), a field-programmable gate array (FPGA), a digital signal processor, an encryption processor, a micro processor, a micro controller, or an application-specific integrated circuit (ASIC). The memory semiconductor chip may be, for example, a volatile memory semiconductor chip, such as a dynamic random access memory (DRAM), or a static random access memory (SRAM). As another example, the memory semiconductor chip may be a non-volatile memory semiconductor chip, such as a Phase-change RAM (PRAM), a Magnetoresistive RAM (MRAM), a Ferroelectric RAM (FeRAM) or a Resistive RAM (RRAM).

The molding layer 260 may be disposed on the wiring structure 170. The molding layer 260 may be on and at least partially cover the wiring structure 170. The molding layer 260 may be on and may wrap at least a part of the chip stack 200. The molding layer 260 may be on and may wrap a side face of the chip stack 200. For example, the molding layer 260 may at least partially expose the upper face of the chip stack 200. As another example, the molding layer 260 may be no and at least partially cover the upper face of the chip stack 200. The molding layer 260 may include an insulating material, for example, an insulating polymer material, such as EMC.

The conductive post 265 may be disposed on the wiring structure 170. The conductive post 265 may penetrate or extend through the molding layer 260. The conductive post 265 may be spaced apart from the chip stack 200. The conductive post 265 is electrically connected to the thermal pad 178. In some embodiments, the conductive post 265 may be in contact with the thermal pad 178.

The conductive post 265 may be a pillar structure having a predetermined height. The conductive post 265 may include a metal such as copper (Cu). In some embodiments, the conductive post 265 may be formed by forming a seed layer and performing an electroplating process using the seed layer. The seed layer, for example, the seed metal 135a, may include various metals, such as copper (Cu), titanium (Ti), tantalum (Ta), titanium nitride (TiN), and/or tantalum nitride (TaN).

The number, intervals, placement forms, and the like of the through via 165, the second pad 162, the wiring vias 174V1, 174V2 and 174V3, the wiring pad 176, the thermal pad 178, and the conductive post 265 are not limited to those shown in the drawings, and may vary depending on the design in accordance with different embodiments.

The heat transfer material layer 310 may be disposed on the molding layer 260. The heat transfer material layer 310 may be on and at least partially cover the conductive posts 265. The heat transfer material layer 310 may be in contact with the conductive posts 265. The heat transfer material layer 310 may be disposed, for example, on the upper face of the chip stack 200 and on the upper face of the molding layer 260.

The heat transfer material layer 310 may include, for example, a thermal interface material (TEM). The heat transfer material layer 310 may include, for example, a heat conductive adhesive tape, a heat conductive grease, a heat conductive adhesive, and the like. The heat transfer material layer 310 may include, for example, one or more metal materials, such as, but not limited to, silver (Ag), aluminum (Al), copper (Cu), gold (Au), zinc (Zn), nickel (Ni), and/or iron (Fe) or an alloy of the metal materials

A heat dissipation member 320 may be disposed on the heat transfer material layer 310. The heat dissipation member 320 may be bonded onto the molding layer 260 and the conductive post 265 by the heat transfer material layer 310.

The heat dissipation member 320 may be, for example, a heat sink, a heat spreader, a heat pipe, and the like. The heat dissipation member 320 may include, for example, silver (Ag), copper (Cu), nickel (Ni), gold (Au) or a combination thereof.

According to some embodiments, the heat transfer material layer 310 and the heat dissipation member 320 may be omitted.

In the semiconductor package according to some embodiments, the first semiconductor chip 100, which generates relatively more heat, may be thermally connected to the thermal pad 178, the through vias 165, and the conductive post 265. Therefore, the heat generated in the first semiconductor chip 100 may be dispersed in various directions. For example, the heat generated in the first semiconductor chip 100 may be discharged to the thermal pad 178 through the wiring structure 170, and may be discharged to the through vias 165 and/or the conductive posts 265 through the wiring structure 170. That is, the heat generated in the first semiconductor chip 100 may be discharged in a vertical direction and/or a horizontal direction. Therefore, the heat dissipation characteristics of the semiconductor package may be improved and/or enhanced.

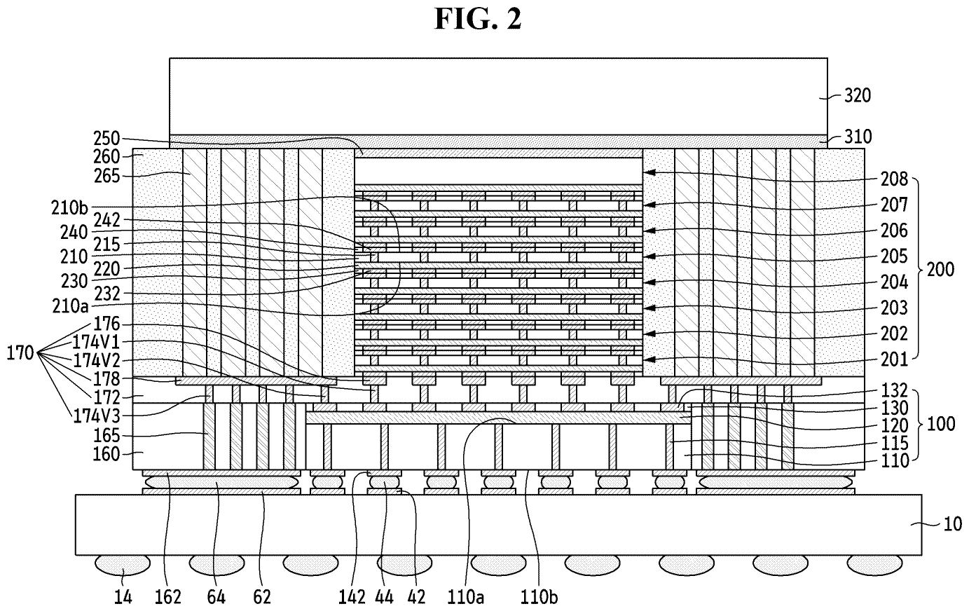

FIGS. 2 to 10 are diagrams that further illustrate a semiconductor package according to some embodiments. For convenience of explanation, repeated parts of contents describe above using FIG. I will be briefly described or omitted.

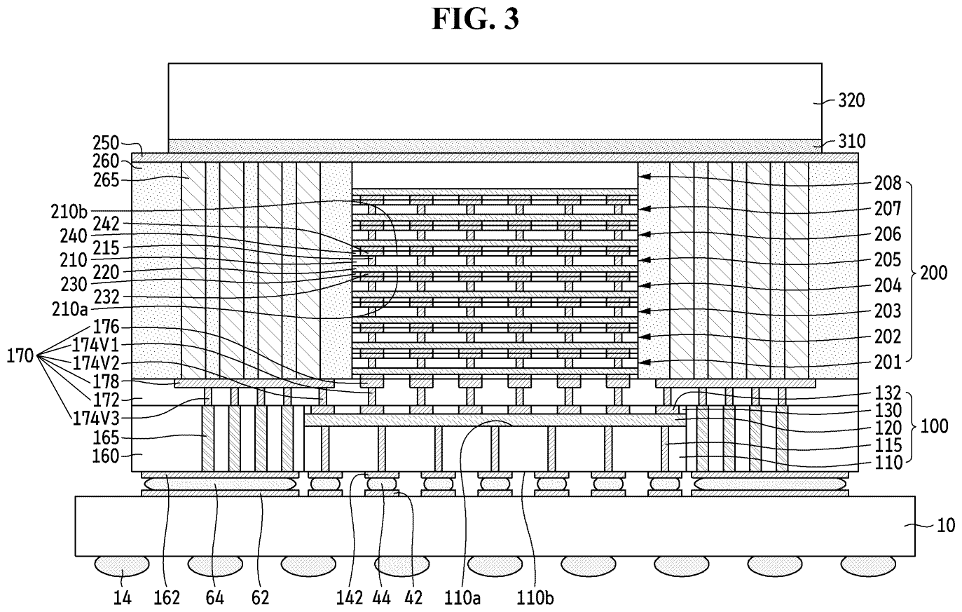

Referring to FIGS. 2 and 3, the semiconductor package according to some embodiments may further include a metal foil layer 250. The metal foil layer 250 may be a copper (Cu) foil.

Referring to FIG. 2, in the semiconductor package according to some embodiments, the metal foil layer 250 may be disposed on the chip stack 200. The metal foil layer 250 may be disposed on the upper face of the chip stack 200. The metal foil layer 250 may extend along the upper face of the chip stack 200. The molding layer 260 may at least partially expose the upper face of the metal foil layer 250.

Referring to FIG. 3, in the semiconductor package according to some embodiments, the metal foil layer 250 may be disposed on the chip stack 200 and the molding layer 260. The metal foil layer 250 may extend along the upper face of the chip stack 200 and the upper face of the molding layer 260. The metal foil layer 250 may be disposed on the conductive posts 265.

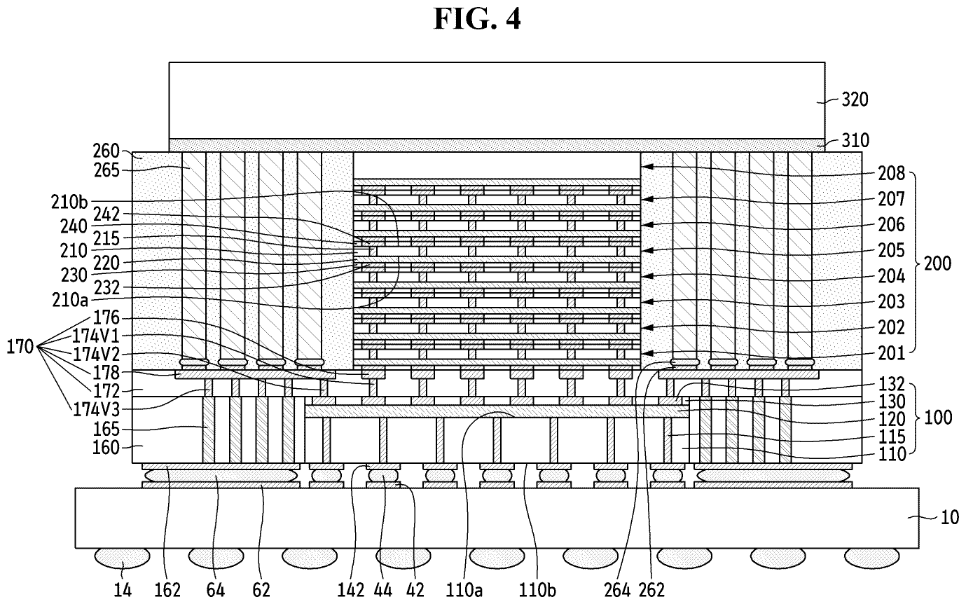

Referring to FIG. 4, in the semiconductor package according to some embodiments, a first conductive pad 262 and a solder ball 264 may be disposed between the conductive post 265 and the thermal pad 178.

The first conductive pad 262 may be disposed on the thermal pad 178. The first conductive pad 262 may be connected to the thermal pad 178. The first conductive pad 262 and the thermal pad 178 may include, for example, copper (Cu).

The solder ball 264 may be disposed between the first conductive pad 262 and the conductive post 265. The solder ball 264 may electrically connect the first conductive pad 262 and the conductive post 265.

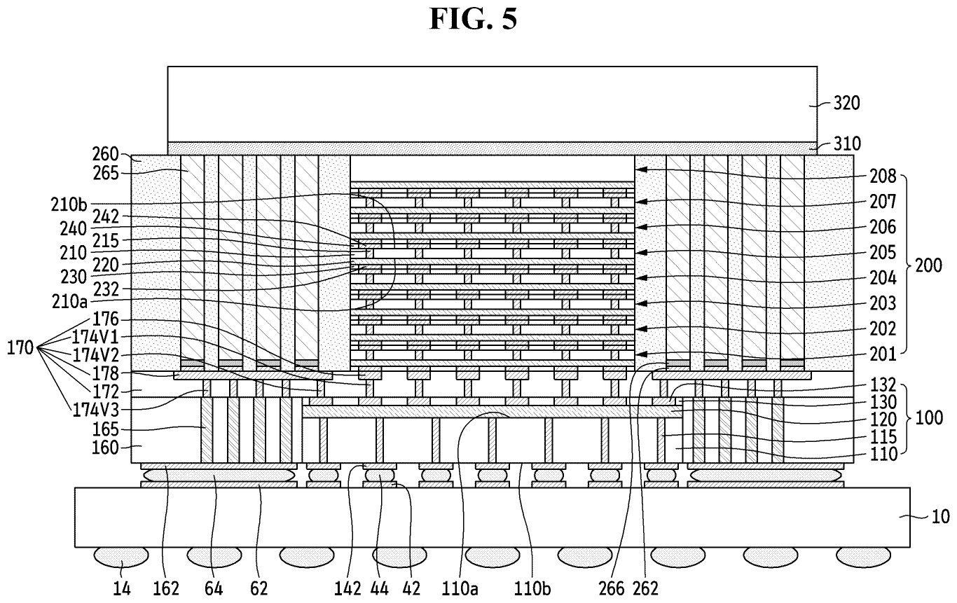

Referring to FIG. 5, in the semiconductor package according to some embodiments, the first conductive pad 262 and the second conductive pad 266 may be disposed between the conductive post 265 and the thermal pad 178.

The first conductive pad 262 may be disposed on the thermal pad 178. The first conductive pad 262 may be connected to the thermal pad 178. The first conductive pad 262 and the thermal pad 178 may include, for example, copper (Cu).

The second conductive pad 266 may be disposed between the first conductive pad 262 and the conductive post 265. The second conductive pad 266 may electrically connect the first conductive pad 262 and the conductive post 265. The second conductive pad 266 may be disposed on the lower face of the first conductive pad 262. The second conductive pad 266 may include, for example, tin (Sn).

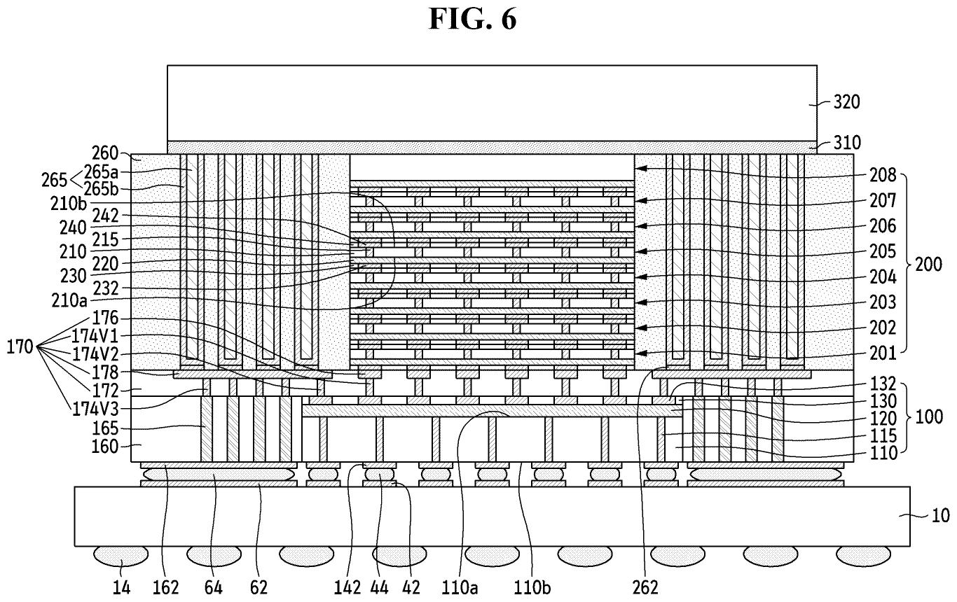

Referring to FIG. 6, in the semiconductor package according to some embodiments, the first conductive pad 262 may be disposed between the conductive post 265 and the thermal pad 178. The first conductive pad 262 may be connected to the thermal pad 178. The conductive post 265 may include a first conductive film 265a and a second conductive film 265b.

The first conductive film 265a may have a pillar structure having a predetermined height. The second conductive film 265b may extend along the side face and the lower face of the first conductive film 265a. The second conductive film 265b may at least partially expose the upper face of the first conductive film 265a.

For example, the first conductive pad 262 and the first conductive film 265a may include copper (Cu), and the second conductive film 265b may include tin (Sn).

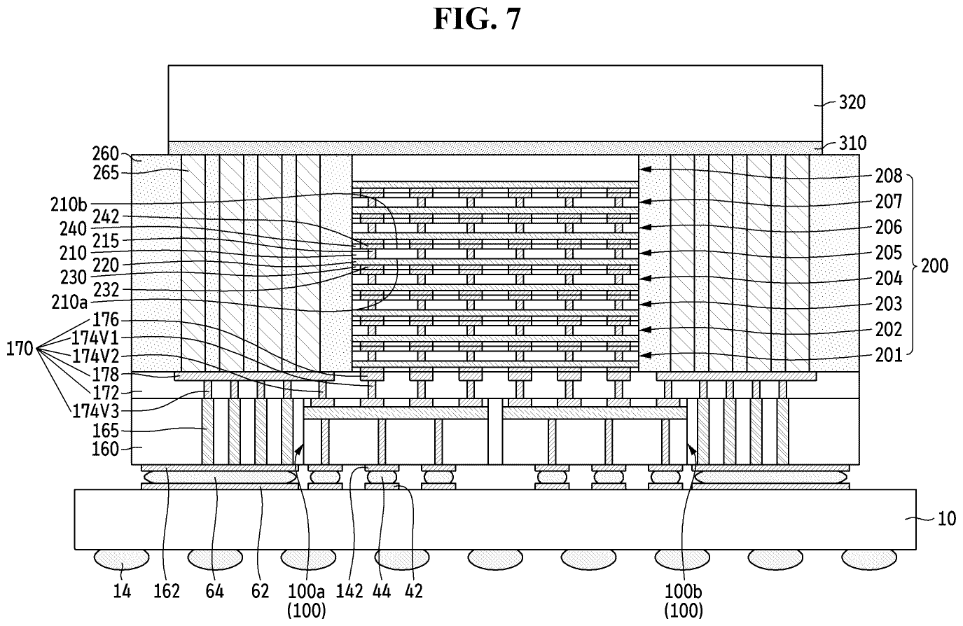

Referring to FIG. 7, the semiconductor package according to some embodiments may include a first logic semiconductor chip 100a, a second logic semiconductor chip 100b, and a chip stack 200.

The first logic semiconductor chip 100a and the second logic semiconductor chip 100b may be disposed on the upper side of the package substrate 10. The first logic semiconductor chip 100a and the second logic semiconductor chip 100b may be mounted on the package substrate 10. The first logic semiconductor chip 100a and the second logic semiconductor chip 100b may be spaced apart on the package substrate 10. The first logic semiconductor chip 100a and the second logic semiconductor chip 100b may be the same or similar to the first semiconductor chip 100 of FIG. 1, and therefore a detailed description thereof will not be provided.

The wiring structure 170 may be electrically connected to the first logic semiconductor chip 100a and the second logic semiconductor chip 100b. The conductive posts 265 may be electrically connected to the first logic semiconductor chip 100a and the second logic semiconductor chip 100b.

The chip stack 200 may be disposed on the first logic semiconductor chip 100a and the second logic semiconductor chip 100b. The chip stack 200 may be electrically connected to the first logic semiconductor chip 100a and the second logic semiconductor chip 100b. That is, the chip stack 200 may be electrically connected to a plurality of first semiconductor chips 100.

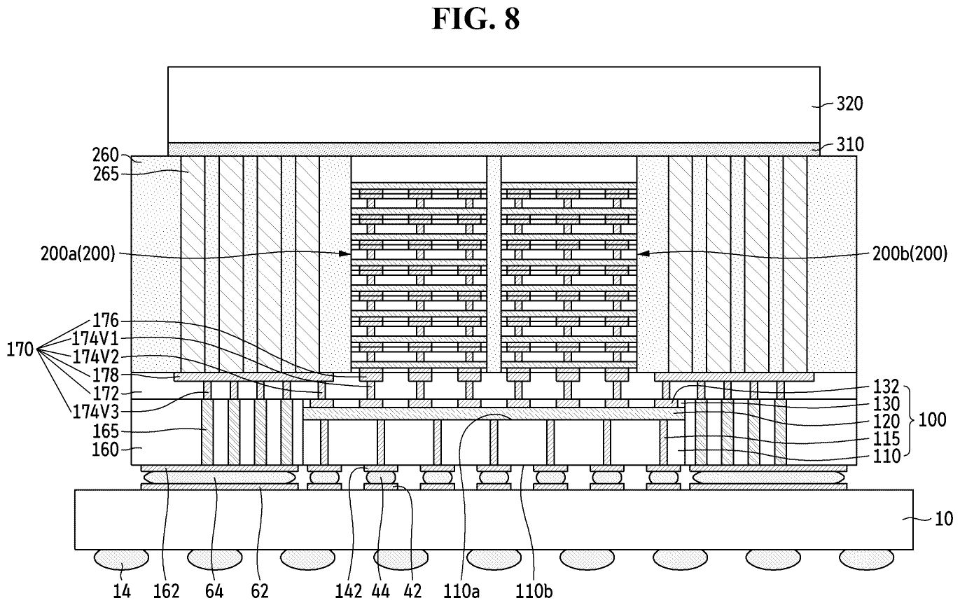

Referring to FIG. 8, the semiconductor package according to some embodiments may include a first semiconductor chip 100, a first chip stack 200a, and a second chip stack 200b.

The first chip stack 200a and the second chip stack 200b may be disposed on the wiring structure 170. The first chip stack 200a and the second chip stack 200b may be spaced apart from each other on the wiring structure 170. Each of the first chip stack 200a and the second chip stack 200b may be the same as or similar to the chip stack 200 of FIG. 1, and therefore a detailed description thereof will not be provided.

The first chip stack 200a and the second chip stack 200b may be electrically connected to the wiring structure 170. The first chip stack 200a and the second chip stack 200b may be electrically connected to the first semiconductor chip 100. That is, the plurality of chip stacks 200 may be electrically connected to the first semiconductor chip 100.

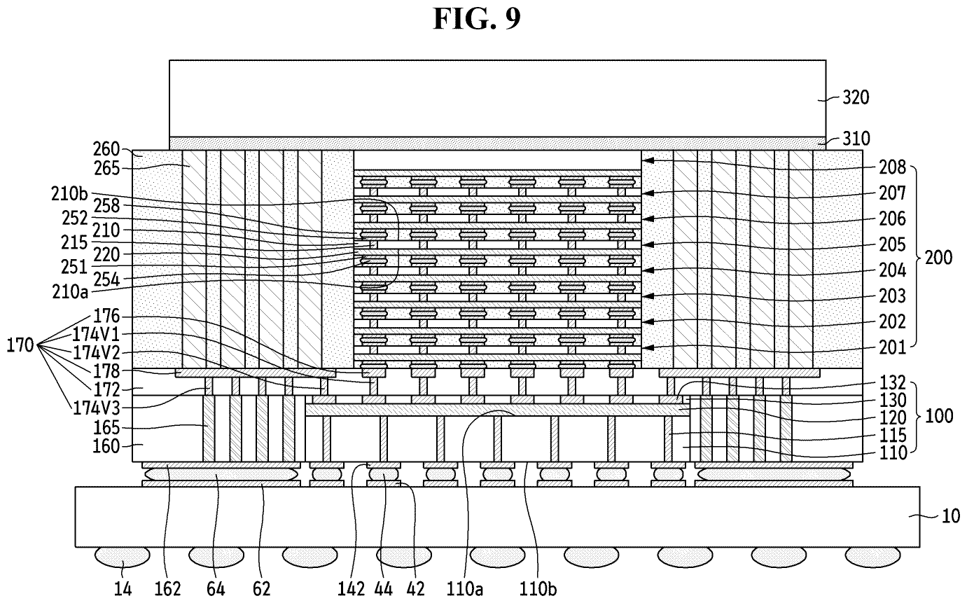

Referring to FIG. 9, in the semiconductor package according to some embodiments, the second semiconductor chips 201 to 208 adjacent to each other may be electrically connected to each other by a third connection terminal 254. The third connection terminal 254 may be disposed between the second semiconductor chips 201 to 208 adjacent to each other. The chip stack 200 may be electrically connected to the wiring structure 170 by the third connection terminal 254.

Each of the second semiconductor chips 201 to 207 may include a second semiconductor substrate 210, a second through electrode 215, a second semiconductor element layer 220, a lower pad 251, and an upper pad 252. The lower pad 251 may be disposed on the second semiconductor element layer 220. The second semiconductor chip 208 may include a second semiconductor substrate 210, a second semiconductor element layer 220, a lower pad 251, and an upper pad 252. The lower pad 251 may be electrically connected to the second semiconductor element layer 220. The upper pad 252 may be disposed on the second side 210b of the second semiconductor substrate 210. The upper pad 252 may be electrically connected to the second through electrode 215.

The third connection terminal 254 may be disposed between the lower pad 251 and the upper pad 252 adjacent to each other. The third connection terminal 254 may connect the lower pad 251 and the upper pad 252 adjacent to each other. For example, the third connection terminal 254 may be disposed between the upper pad 252 of the second semiconductor chip 201 and the lower pad 251 of the second semiconductor chip 202.

The third connection terminal 254 may be disposed between the chip stack 200 and the wiring structure 170. The third connection terminal 254 may be disposed between the lower pad 251 of the second semiconductor chip 201 and the wiring pad 176 of the wiring structure 170. The third connection terminal 254 may connect the lower pad 251 of the second semiconductor chip 201 and the wiring pad 176 of the wiring structure 170.

The third connection terminal 254 may include a conductive material, for example, solder, tin (Sn), silver (Ag), copper (Cu), and/or aluminum (Al). The third connection terminal 254 may have various shapes, such as a land, a ball, a pin, and a pillar. The number, interval, arrangement form, and the like of the third connection terminal 254 are not limited to those shown in the drawings, and may vary depending on the design.

An underfill material layer 258 may be on and may wrap the third connection terminal 254 between the second semiconductor chips 201 to 208 adjacent to each other. The underfill material layer 258 may at least partially fill the gap between the second semiconductor chips 201 to 208 adjacent to each other. The underfill material layer 258 may be on and may wrap the third connection terminal 254 between the second semiconductor chip 201 and the wiring structure 170. The underfill material layer 258 may at least partially fill the gap between the chip stack 200 and the wiring structure 170. The underfill material layer 258 may include, for example, an epoxy resin.

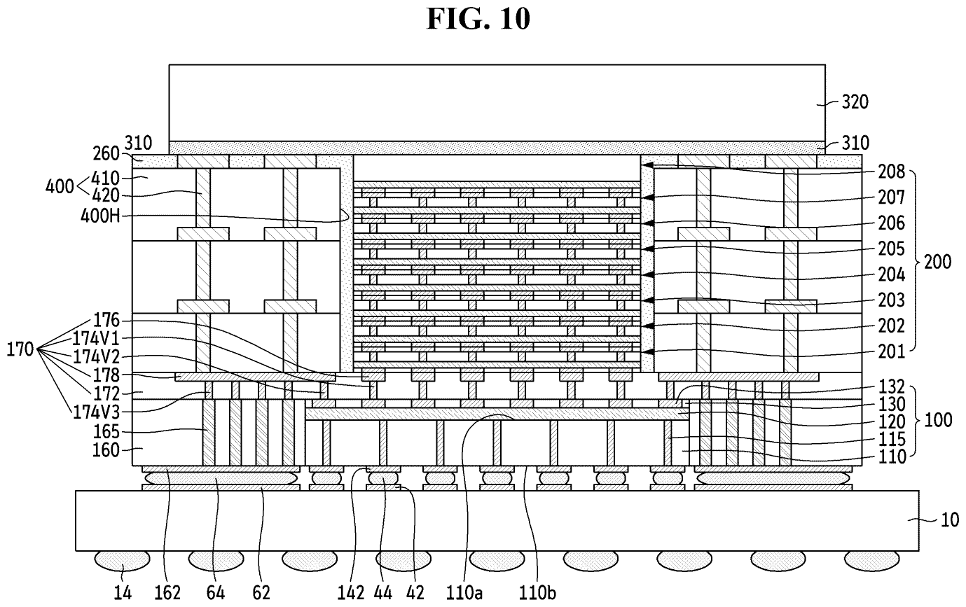

Referring to FIG. 10, a semiconductor package according to some embodiments may include a connection substrate 400. The connection substrate 400 may be disposed on the wiring structure 170. The lower side of the connection substrate 400 may be in contact with the wiring structure 170.

The connection substrate 400 may include a plurality of insulating patterns 410 and a plurality of conductive patterns 420. The plurality of insulating patterns 410 may be stacked in the vertical direction. Each conductive pattern 420 may be disposed inside the respective insulating patterns 410. The conductive pattern 420 may penetrate or extend through the insulating pattern 410. The conductive pattern 420 may penetrate or extend through the insulating pattern 410, and be electrically connected to the wiring structure 170. The conductive pattern 420 may be connected to the thermal pad 178 of the wiring structure 170. The conductive pattern 420 may penetrate or extend through the insulating pattern 410 to come into contact with the heat transfer material layer 310.

The connection substrate 400 may include a through hole 400H penetrating or extending through the inside of the connection substrate 400. The through hole 400H may at least partially expose an upper face of the wiring structure 170. The chip stack 200 may be disposed inside the through hole 400H. The chip stack 200 may be spaced apart from the connection substrate 400.

The molding layer 260 may be on and at least partially cover the connection substrate 400. The molding layer 260 may at least partially fill a space between the connection substrate 400 and the chip stack 200. The molding layer 260 may at least partially fill a space between the connection substrate 400 and the heat transfer material layer 310. The molding layer 260 may at least partially expose an uppermost face of the conductive pattern 420.

The first semiconductor chip 100 may be thermally connected to the thermal pad 178, the through via 165, and the conductive pattern 420. Heat generated in the first semiconductor chip 100 may be dispersed in various directions. The heat generated in the first semiconductor chip 100 may be discharged to the thermal pad 178 through the wiring structure 170 and discharged to the through vias 165 and/or the conductive pattern 420 through the wiring structure 170.

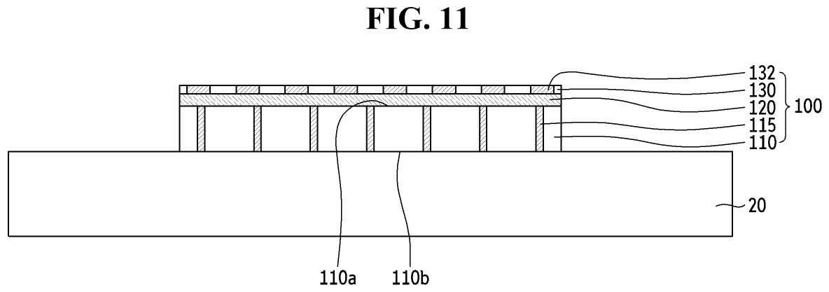

FIGS. 11 to 16 are intermediate stage diagrams that illustrate a method for fabricating a semiconductor package according to some embodiments. For convenience of explanation, repeated parts of contents described above using FIGS. 1 to 10 will be briefly described or omitted.

Referring to FIG. 11, the first semiconductor chip 100 may be formed on a carrier substrate 20. The carrier substrate 20 may be, for example, a semiconductor substrate, a glass substrate, a ceramic substrate or a plastic substrate.

The first semiconductor chip 100 may include a first semiconductor substrate 110, a first through electrode 115, a first semiconductor element layer 120, a chip insulating layer 130, and a chip pad 132. The first semiconductor chip 100 may be formed on the carrier substrate 20 such that the second side 110b of the first semiconductor substrate 110 faces the carrier substrate 20.

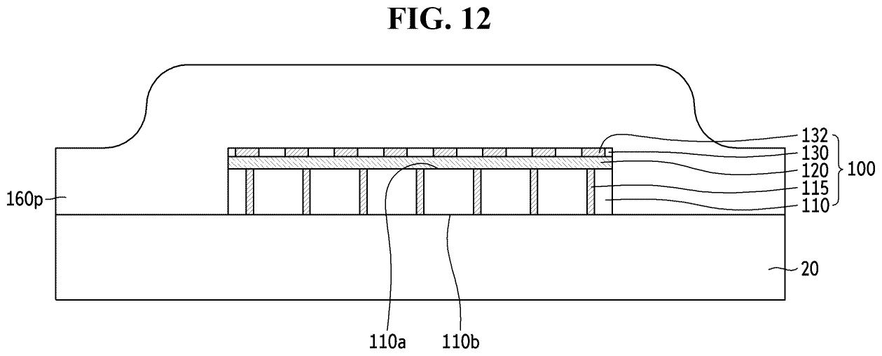

Referring to FIG. 12, a pre-insulating film 160p may be formed on the carrier substrate 20. The pre-insulating film 160p may be on and at least partially cover the carrier substrate 20 and the first semiconductor chip 100. The pre-insulating film 160p may be on and at least partially cover the upper side of the carrier substrate 20 and the upper face and side face of the first semiconductor chip 100.

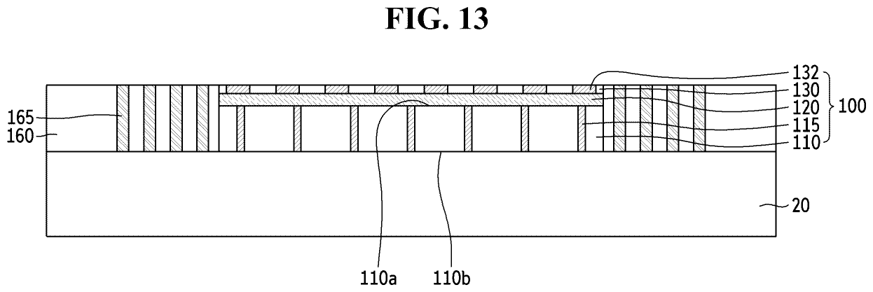

Referring to FIG. 13, an insulating layer 160 and a through via 165 may be formed.

The insulating layer 160 may be formed by performing a planarization process on the upper face of the pre-insulating film 160p. The insulating layer 160 may at least partially expose the upper face of the first semiconductor chip 100. The chip insulating layer 130 and the chip pad 132 of the first semiconductor chip 100 may be at least partially exposed.

A through via 165 may be formed in the insulating layer 160. The through via 165 may penetrate or extend through the insulating layer 160.

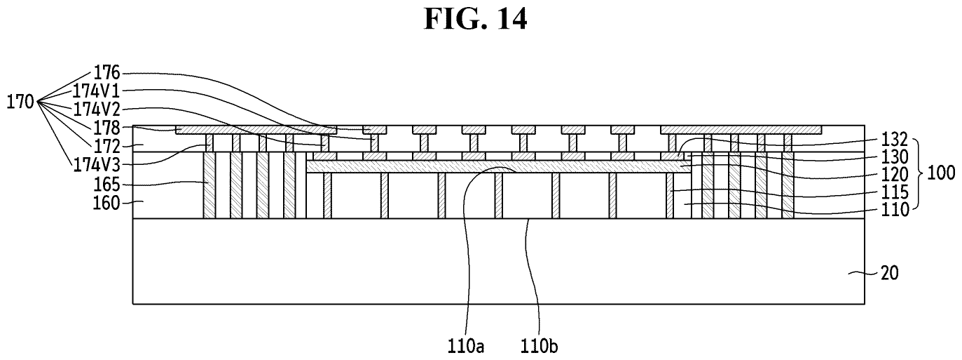

Referring to FIG. 14, a wiring structure 170 may be formed on the first semiconductor chip 100 and the insulating layer 160.

The wiring structure 170 may include a wiring insulating layer 172, wiring vias 174V1, 174V2 and 174V3, a wiring pad 176, and a thermal pad 178. The wiring insulating layer 172 may be on and at least partially cover the first semiconductor chip 100 and the insulating layer 160. The wiring vias 174V1, 174V2 and 174V3, the wiring pad 176, and the thermal pad 178 may be formed in the wiring insulating layer 172. The first and second wiring vias 174V1 and 174V2 may be formed on the first semiconductor chip 100. The third wiring via 174V3 may be formed on the through via 165. The wiring pad 176 may be formed on the first wiring via 174V1. The thermal pad 178 may be formed on the second and third wiring vias 174V2 and 174V3. The wiring insulating layer 172 may at least partially expose the upper face of the thermal pad 178 and the upper face of the wiring pad 176.

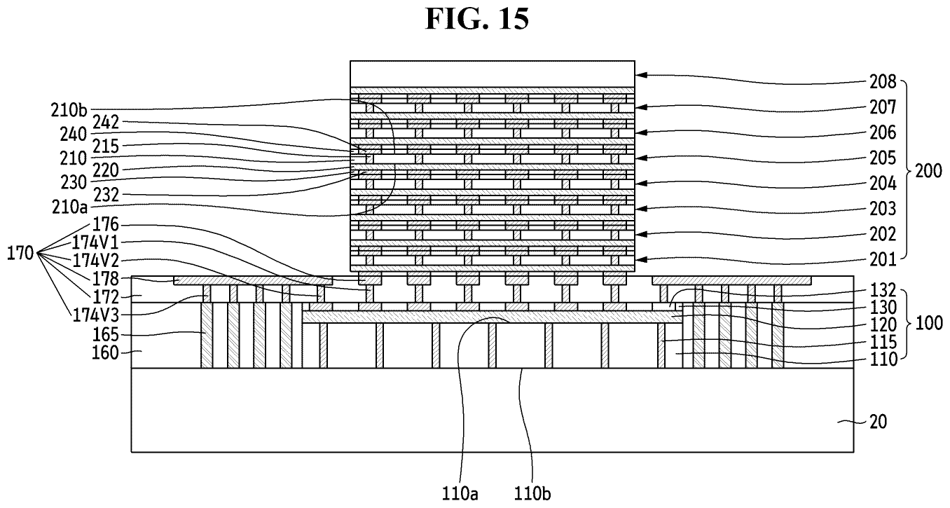

Referring to FIG. 15, a chip stack 200 may be formed on the wiring structure 170. The chip stack 200 may be electrically connected to the wiring structure 170. Each of the second bonding insulating layer 240 and the second bonding pad 242 of the second semiconductor chip 201 may be bonded to each of the wiring insulating layer 172 and the first bonding pad 232 of the wiring structure 170.

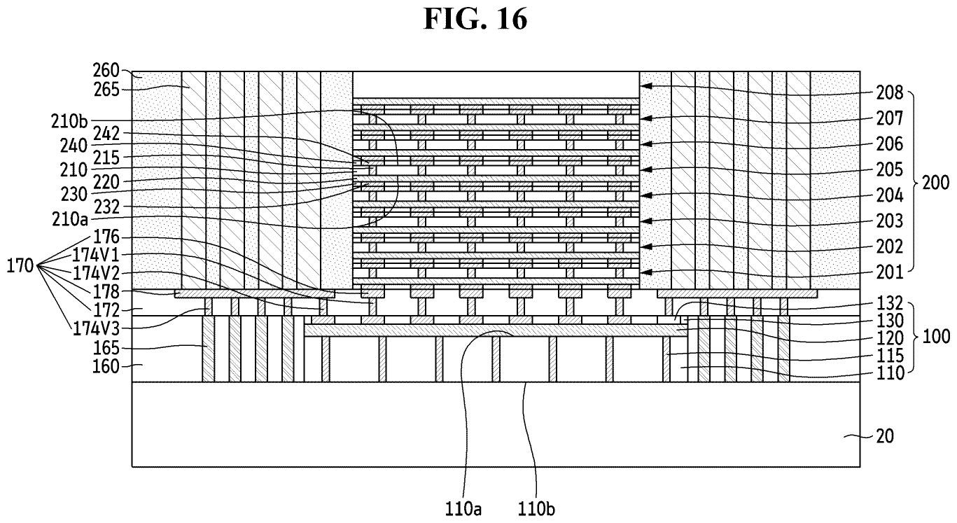

Referring to FIG. 16, a molding layer 260 and a conductive post 265 may be formed on the wiring structure 170. The molding layer 260 may be on and at least partially cover the wiring structure 170 and the chip stack 200. The molding layer 260 may be on and may wrap the chip stack 200. The conductive post 265 may penetrate or extend through the molding layer 260, and be connected to the thermal pad 178.

For example, the conductive post 265 may be formed on the thermal pad 178 of the wiring structure 170. The conductive post 265 may be formed, for example, by forming a seed layer and performing an electroplating process using the seed layer. Next, the molding layer 260 that at least partially covers the conductive post 265 and the chip stack 200 may be formed. A planarization process may be performed on the upper face of the molding layer 260 to at least partially expose the upper face of the conductive post 265 and/or the upper face of the chip stack 200. In some embodiments, a part of the upper part of the conductive post 265 may be removed together in the planarization process.

For example, after the molding layer 260 that at least partially covers the wiring structure 170 and the chip stack 200 is formed, a hole that penetrates or extends through the molding layer 260 and at least partially exposes the upper face of the thermal pad 178 may be formed. The conductive post 265 may be formed by performing a plating process on the hole. For example, the conductive post 265 may be formed by a plating process, an electroless plating process, a vapor deposition process, or the like. A planarization process may be performed on the upper face of the molding layer 260 to at least partially expose the upper face of the conductive post 265 and/or the upper face of the chip stack 200. In some embodiments, a part of the upper part of the conductive post 265 may be removed together in the planarization process.

Next, referring to FIG. 1, a heat transfer material layer 310 and a heat dissipation member 320 may be formed on the molding layer 260.

The carrier substrate 20 may be removed to at least partially expose the through via 165 and the first semiconductor chip 100. For example, the carrier substrate 20 may be removed after attaching the carrier substrate onto the heat dissipation member 320. A first pad 142 may be formed on the exposed first semiconductor chip 100, and a second pad 162 may be formed on the at least partially exposed through via 165. A first connection terminal 44 may be formed on the first pad 142, and a second connection terminal 64 may be formed on the second pad 162.

Subsequently, a package including the first semiconductor chip 100, the insulating layer 160, the through via 165, the wiring structure 170, the chip stack 200, the molding layer 260, the conductive post 265, the heat transfer material layer 310 and the heat dissipation member 320 may be formed on the package substrate 10. The first connection terminal 44 may be connected to the first substrate pad 42, and the second connection terminal 64 may be connected to the second substrate pad 62.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit of the present disclosure. Accordingly, the above-described embodiments should be understood in all respects as illustrative and not restrictive.

What is claimed is:

1. A semiconductor package comprising:
a first semiconductor chip;
an insulating layer on a side face of the first semiconductor chip;
a through via which extends through the insulating layer;
a wiring structure, which is electrically connected to the first semiconductor chip and the through via, on the first semiconductor chip and the insulating layer;
a chip stack on the wiring structure;
a molding layer on at least a part of the chip stack and on the wiring structure; and
a conductive post, which extends through the molding layer and is electrically connected to the wiring structure.

2. The semiconductor package of claim 1, further comprising:
a connection terminal between the wiring structure and the conductive post.

3. The semiconductor package of claim 1,
wherein the wiring structure and the conductive post are in direct contact with each other.

4. The semiconductor package of claim 1,
wherein the conductive post includes a first metal film, and a second metal film on the first metal film, the second metal film including a material different from the first metal film.

5. The semiconductor package of claim 1,
wherein the chip stack includes stacked second semiconductor chips, a bonding insulation layer, and a bonding pad between the second semiconductor chips adjacent to each other.

6. The semiconductor package of claim 1,
wherein the chip stack includes stacked second semiconductor chips and a connection terminal between the second semiconductor chips adjacent to each other.

7. The semiconductor package of claim 1, further comprising:
a metal foil layer on the chip stack.

8. The semiconductor package of claim 1, further comprising:
a metal foil layer on the chip stack and the molding layer.

9. The semiconductor package of claim 1, further comprising:
a heat dissipation member on the chip stack and the molding layer.

10. The semiconductor package of claim 1,
wherein the wiring structure includes a wiring insulation layer, a wiring pad, and a thermal pad inside the wiring insulation layer,
wherein the chip stack includes a bonding insulation layer and a bonding pad,
wherein the wiring insulation layer contacts the bonding insulation layer,
wherein the wiring pad contacts the bonding pad, and
wherein the thermal pad contacts the conductive post.

11. A semiconductor package comprising:
an insulating layer;
a first logic semiconductor chip in the insulating layer;
a through via inside the insulating layer, spaced apart from the first logic semiconductor chip;
a wiring structure on the insulating layer, electrically connected to the first logic semiconductor chip and the through via; and
a first chip stack, which includes stacked first memory semiconductor chips that are configured without a buffer chip, on the wiring structure.

12. The semiconductor package of claim 11, further comprising:
a second chip stack, which includes stacked second semiconductor memory chips that are configured without the buffer chip, on the wiring structure.

13. The semiconductor package of claim 11, further comprising:
a second logic semiconductor chip inside the insulating layer, spaced apart from the first logic semiconductor chip, and electrically connected to the wiring structure.

14. The semiconductor package of claim 11,
wherein the wiring structure includes a wiring insulating layer and a wiring pad in the wiring insulating layer,
wherein the chip stack includes a bonding insulating layer and a bonding pad,
wherein the wiring insulating layer contacts the bonding insulating layer, and
wherein the wiring pad contacts the bonding pad.

15. The semiconductor package of claim 11,
wherein the logic semiconductor chip includes a semiconductor substrate and a first semiconductor element layer of the semiconductor substrate, and
wherein the first semiconductor element layer is between the wiring structure and the semiconductor substrate.

16. The semiconductor package of claim 11, further comprising:
a connection substrate on the wiring structure, the connection substrate including a through hole extending through the connection substrate, and a conductive pattern electrically connected to the wiring structure,
wherein the first logic semiconductor chip is inside the through hole.

17. The semiconductor package of claim 11, further comprising:
a conductive post on the wiring structure, the conductive post being electrically connected to the wiring structure.

18. A semiconductor package comprising:
a package substrate;
a first semiconductor chip on the package substrate;
an insulating layer on a side face of the first semiconductor chip;
a through via which extends through the insulating layer;
a wiring structure, which is electrically connected to the first semiconductor chip and the through via, on the first semiconductor chip and the insulating layer;
a chip stack on the wiring structure and electrically connected thereto;
a molding layer on at least a part of the chip stack and on the wiring structure;
a conductive post, which extends through the molding layer and is electrically connected to the wiring structure;
a heat transfer material layer on the molding layer; and
a heat dissipation member on the heat transfer material layer.

19. The semiconductor package of claim 18,
wherein the semiconductor chip includes a logic semiconductor chip, and
wherein the chip stack includes stacked memory semiconductor chips that are configured without a buffer chip.

20. The semiconductor package of claim 18,
wherein the wiring structure and the chip stack are bonded by hybrid bonding.
